(19) United States
(12) Patent Application Publication
(10) Pub. No.: US 2015/0321739 A1
(43) Pub. Date: Nov. 12, 2015

(54) MARINE SUBSURFACE DATA CENTER VESSEL

(71) Applicant: Aquantis, Inc., Santa Barbara, CA (US)

(72) Inventor: James G.P. Dehlsen, Santa Barbara, CA (US)

(73) Assignee: Aquantis, Inc., Santa Barbara, CA (US)

(21) Appl. No.: 14/272,656

(22) Filed: May 8, 2014

(51) Int. Cl. B63G 8/00; F25D 1/02; B63G 8/18; B63G 8/36; B63G 8/06; B63B 21/50

(52) U.S. Cl. CPC B63G 8/001; B63G 8/06; B63B 21/50; B63G 8/18; B63G 8/36; F25D 1/02

(57) ABSTRACT

The present invention provides a submersible data center vessel that is towed to its operating site, moored to anchors on the ocean floor and connected to an appropriate power generating system. The vessel is then submerged to its recommended operating depth while preferably still allowing air exchange and service crew access to the vessel interior. In the event of extreme weather/sea conditions, the vessel can be submerged deeper for the duration of the extreme conditions and out of range of harmful wind and wave forces. The subsurface vessel is preferably powered by a renewable energy source such as, but not limited to marine hydrokinetic energy provided by wave, tidal, or marine current electric generators and/or offshore wind turbines. Alternatively, an onshore electric power grid supplies a portion or all of the electric power by submarine cable to the vessel. The computer servers housed within the vessel are cooled by heat exchangers drawing from cool ocean water, and continue to operate irrespective of weather and sea conditions on the surface.

### BACKGROUND OF THE INVENTION

1. Field of Invention

This invention relates to data centers and, more specifically, to a submersible data center vessel that is preferably powered by a renewable energy source.

2. Description of Related Art

A data center comprises a large group of networked computer servers that are used by organizations for the remote storage, processing, and/or distribution of large amounts of data. By many estimates, the most significant operational cost of a data center is the recurring power cost—electricity. The cost of electrical power has been the bane of data center professionals for the last couple of decades. Alternative data center models include ways to reduce the cost of powering huge farms of servers. Also, in operation, data centers produce significant amounts of thermal energy, i.e., heat, which must be extracted for efficient operation and can account for up to 50% of the data center electricity requirements. Heat extraction is typically performed using ventilation and/or cooling by an electric powered refrigerator. Accordingly, data centers are frequently located near rivers or bodies of water, which are used for cooling purposes.

The various implementations and types of data centers are readily apparent to one of ordinary skill in the art. For example, U.S. Pat. No. 7,278,273 to Whitted, the entire disclosure of which is incorporated by reference herein, describes a modular data center with modular components suitable for use with rack or shelf mount computing systems. The modular data center is housed in an intermodal shipping container and computing systems mounted within the container are configured to be shipped and operated within the container. The modular data center includes a temperature control system for maintaining the air temperature surrounding the computing systems.

U.S. Pat. No. 7,525,207 to Clidara et al., the entire disclosure of which is incorporated by reference herein, describes a container transport ship with computer servers located in shipping containers, which are cooled by ocean water that is pumped through heat exchangers. Electric power is supplied by wave or marine current electric power generating devices connected by power cables to the ship. Such a floating vessel is vulnerable to extreme weather and sea states. Ocean vessel operators typically steer away from areas where intense storms and/or destructive wave action are present in order to avoid potential damage to their vessels and cargo.

The ship in the '207 patent is connected to wave or marine current generating systems for its electric power for cooling and processing/computing. Any interruption or disconnection of the power supply and cooling water can be highly detrimental to data center operation. The floating container vessel does not benefit from the heat extraction potential of the vessel hull surface area below the water line, which could fulfill a significant fraction of the total server center heat extraction requirement. The surface floating vessel data center approach therefore has limited application.

### SUMMARY OF THE INVENTION

The present invention overcomes these and other deficiencies of the prior art by providing a submersible data center vessel that is towed to its operating site, moored to anchors on the ocean floor and connected to fiber optic cables of the computer network it serves, and to an appropriate marine hydrokinetic generating system. The vessel is then submerged to its recommended operating depth while preferably still allowing air exchange and service crew access to the vessel interior. In the event of extreme weather/sea conditions, the vessel can be submerged deeper for the duration of the extreme conditions and out of range of harmful wind and wave forces.

The subsurface vessel is preferably powered by a renewable energy source such as, but not limited to marine hydrokinetic energy provided by wave or marine currents, both gyre and tidal, electric generators and/or offshore wind turbines. Alternatively, an onshore electric power grid connected by submarine cable supplies a portion or all of the electric power for the vessel. The vessel could also have its own on-board electric power generators or energy storage capacity such as batteries. The computer servers housed within the vessel are cooled by heat exchangers drawing from cool ocean water, and continue to operate irrespective of weather and sea conditions on the surface.

In an embodiment of the invention, a submergible data center vessel comprises: one or more submergible vessels; and one or more data centers housed within each of the one or more submergible vessels. The one or more submergible vessels are tubular and one of the plurality of submergible vessels comprises a coning tower. The submergible data center vessel further comprises one or more anchoring lines for anchoring the data center vessel and an electrical conductor for receiving electrical power from an external power source. The external power source may be a renewable energy source in the ocean or an onshore power grid connected by submarine cable. The submergible data center vessel further comprises a data communications line to transfer data between the one or more data centers and the Internet. The submergible data center vessel also comprises a heat exchanger. The heat exchanger dissipates heat away from the one or more data centers into water adjacent to the data center vessel. The submergible data center vessel further comprises one or more elevator wings for adjusting an operating depth of the data center vessel. The submersible data center has variable ballast, which can be controlled for depth adjustment. The one or more submergible vessels are accessible from above an ocean surface by a human. The submergible data center vessel is positively buoyant. The submergible data center vessel further comprises inlet piping coupled to the heat exchanger for drawing cold water and a snorkel.

The foregoing, and other features and advantages of the invention, will be apparent from the following, more particular description of the preferred embodiments of the invention, the accompanying drawings, and the claims.

### BRIEF DESCRIPTION OF THE DRAWINGS

For a more complete understanding of the present invention, the objects and advantages thereof, reference is now made to the ensuing descriptions taken in connection with the accompanying drawings briefly described as follows.

FIG. 1 illustrates a data center vessel according to an embodiment of the invention;

FIG. 2 illustrates a top view of the data center vessel of FIG. 1;

FIG. 3 illustrates an end view of the data center vessel of FIG. 1;

FIG. 4 illustrates deployment and operation of the data center vessel of FIG. 1 in normal and extreme conditions according to an embodiment of the invention; and

FIG. 5 illustrates a subsurface data center vessel and ocean current turbine system according to an embodiment of the invention.

### DETAILED DESCRIPTION OF PREFERRED EMBODIMENTS

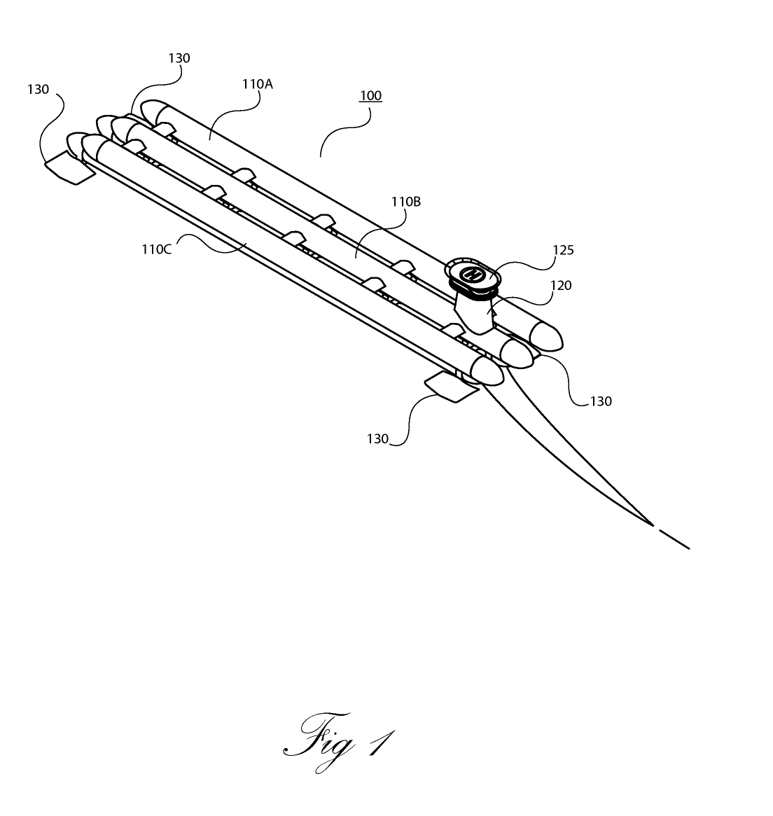

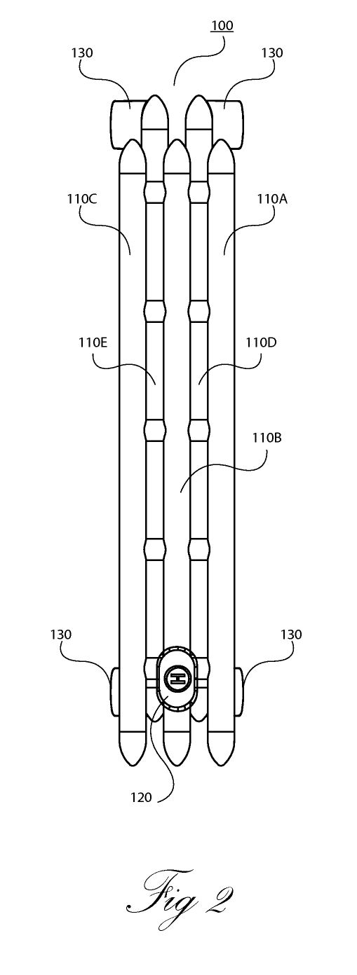

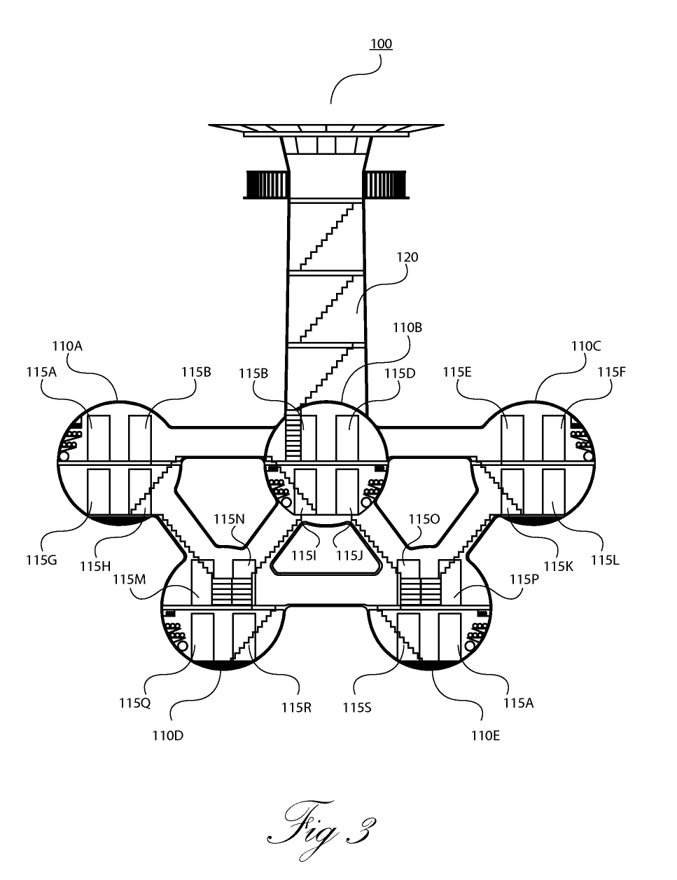

Preferred embodiments of the present invention and their advantages may be understood by referring to FIGS. 1-5, wherein like reference numerals refer to like elements. The data center vessel of the present invention may be deployed in any type of water environment where an energy source is present and connection is made by power cables. Preferably the energy source is a renewable energy source such as a marine hydrokinetic energy generating system. Alternatively, the energy source is an onshore power grid, an on-board power generating system, or both.

FIGS. 1-3 illustrate a data center vessel 100 according to an embodiment of the invention. The data center vessel 100 comprises a number of connected tubular vessel(s) 110A-E. Although five (5) tubular vessels are shown, any number of tubular vessels may be used. Each tubular vessel 110 has a diameter that optimizes structural requirements to the vessel's maximum operating depth and seaworthy requirements and may provide for multiple decks within the tubes. The decks offer floor space for multiple rows of computer server racks running lengthwise on each deck. In an exemplary embodiment of the invention, the data center vessel 100 comprises any number of server racks holding computing systems 115A-T (twenty (20) are shown as an example) mounted and operated on each deck. Heat extraction from the vessel's power consuming processes is by on-board heat exchangers (not shown) using seawater for cooling. In other embodiments of the invention, various other types of data center computing systems may be employed, the identification and implementation of which are apparent to one of ordinary skill in the art. The ends of the tubular vessels 110A-E are capped and at least one of the tubular vessels has a conning tower 120, which in normal operation, extends above the ocean surface and provides access for operation and maintenance by a service crew, and ducting for air exchange and ventilation within. On top of the conning tower is a helipad 125.

In an embodiment of the invention, the tubular vessels 110A-E are fabricated in facilities now commonly used to make wind turbine towers, where a steel plate is rolled and welded together to form large diameter tubes. The tubular sections can be transported by road or rail, and are ideal for subsurface hydrostatic pressure loads and optimizes the use of structural materials. The tubular sections are assembled together at a shipyard where the sections are welded together along with the end caps to form the vessel. The tubular vessels 110A-E are interconnected by smaller diameter steel tubes to provide passageway for the crew and moving components (racks, consoles, etc.) among tubes. The passage way tubes also allow for air movement and plumbing, electrical and fiber optic connection between the tubular vessels 110A-E.

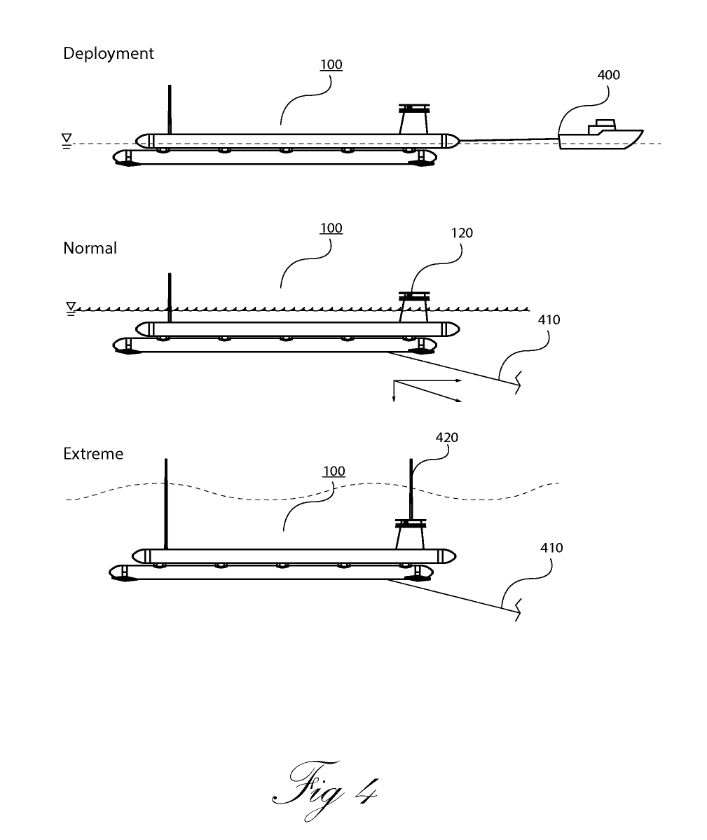

FIG. 4 illustrates deployment and operation of the data center vessel 100 in normal and extreme conditions according to an embodiment of the invention. During deployment (shown at top), the data center vessel 100 is towed to an operating site by a ship 400. At the operating site, anchoring lines 410 are connected, along with electric power cables to a power source, such as wave or marine current generating units (not shown), and a data communications medium, such as fiber optic cables, to a computer network on shore. In an embodiment of the invention, additional cables to shore connect the data center vessel 100 to a supervisory control and data acquisition (SCADA) system (not shown) to allow a shore based operator to remotely monitor and control vessel activity. Ballast water is added to buoyancy tanks in the vessel 100 causing it to descend below the surface to a preferred operating depth while still remaining positively buoyant. Vertical stabilizer wings 130 at each end of the vessel, when pitched, provide further depth adjustment.

During normal operation (shown center), only the conning tower 120 extends above the water surface and the tubular vessels 110A-E stations below any significant wave orbital forces. Under extreme sea/weather conditions (shown bottom), a retractable snorkel tube 420 extending above the conning tower 120 allows the vessel 110 to be submerged further while still providing for the required air exchange to the interior of the vessel. In this scenario, the vessel is out of harm's way and continues to operate with full data center capacity.

In another embodiment of the invention, the data center vessel 100 operates totally submerged or positioned on the ocean floor, connected to the surface by an umbilical breather tube terminating to a float on the surface. The umbilical breather tube is a sufficient diameter to provide for necessary air exchange volume to the vessel.

For cooling the servers, storage, and networking equipment, seawater is drawn through inlet piping (not shown) to onboard heat exchangers where the heat is extracted by the seawater and discharged from the vessel. Any type of heat exchanger may be employed, the identification and implementation of which is apparent to one of ordinary skill in the art. A water intake conduit may be extended from the vessel, deeper in the ocean to reach colder water temperature for added cooling capacity. Significant vessel cooling is also obtained from the heat conduction through the metal surface plates of the entire submerged vessel, thereby transferring the heat through contact to the surrounding seawater. Compared to a surface ship, the tubular vessels 110A-E collectively provide a much greater surface area exposed to the ocean for the dissipation of heat. In another embodiment of the invention, keel cooling is implemented through plate-coil heat exchangers, the implementation of which is apparent too one of ordinary skill in the art.

In a preferred embodiment of the invention, electric power is generated from a renewable energy source. For example, the subsurface data center vessel 100 can be operated in a steady (gyre) current, tidal current, and/or wave regime where the electric power is generated by a marine hydrokinetic generating system specific to the energy resource of the operating site. In another embodiment of the invention, the data center vessel is powered by an onshore electrical power station, which may provide all or a portion of the electrical power needed to power the data center vessel 100. In yet another embodiment of the invention, the data center vessel is powered by a renewable energy source, but is coupled to an onshore electrical power grid as a backup power source.

For example, gyre currents driven by the Coriolis effect and temperature gradients, tend to flow constantly in one direction, although seasonal wind drag on the ocean surface and gravitational forces cause some variance in flow speed and headings. Gyre current energy captured by a subsurface rotor driven generator is an ideal power source for a marine subsurface data center operation due to the high energy density of the swift marine current and small seasonal variation in current speed. This can provide high continuous plant capacity utilization, as with the Gulf Stream where utilization is in the range of 70% of a power plant's total capacity. Under these conditions, the data center may be able to operate “off grid” and eliminate the need for a backup power supply to deal with power interruptions associated with a shore-based power grid. This is accomplished when the minimum level of seasonal flow velocity is reached, which establishes the lowest level of power generating output during the year and that level becomes the baseload generating level which can always be depended upon for the data center requirements. If the data center vessel is connected to an onshore grid, the electric power generated in excess of baseload, could be sold to an electric utility or other off taker.

The subsurface data center vessel 100 moored to the ocean floor in a current speed in the range of 1 to 2.5 meters per second, produces a drag force against the mooring line which has two components: a horizontal force opposing the current direction and a vertical downward force. The vessel 100 also has the downward force of gravity, which is offset with the buoyancy of the vessel and may include a small-added margin of buoyancy for safety. The vessel 100 is streamlined to minimize the horizontal drag, while the downward force is offset by the added buoyancy of the conning tower 120 below the water line, at the forward end (where the mooring lines are attached). Depth adjustment for the vessel is accomplished through a combination of ballasting the vessel with seawater and adjusting the diving planes (similar to a military submarine) herein referred to as vertical stabilizer wings 130. The vessel is fitted with vertical stabilizer wings 130 at the forward end which are pitched simultaneously to create lift or a downward force by the current flow. The forward wings 130, when pitched for lift add an upward force vector which combined with the additional buoyancy of the conning tower, offsets the downward force vector of the mooring line. The aft stabilizer wings 130 pitch in unison, adding lift or generating a downward force as required, thereby maintaining the vessel 100 in a horizontal position at all times.

The adjustable elevator wings 130 at the forward end of the tubes generate lift, which in combination with ballast adjustment stabilizes the vessel to the desired operating depth. Elevator wings 130 at the aft end, adjust the aft end of the vessel to the same depth maintaining the vessel horizontal. Due to the constant current flow, these forward and aft elevator wings enable depth adjustment, keeping the vessel horizontal while ballasting with seawater allows for surfacing and submerging while maintaining positive buoyancy for safety. Pitch actuation of the forward and aft wings 130 provide a means of fine-tuning the operating depth and gaining further depth for total submergence of the conning tower, with only the snorkel tube above the ocean surface, over brief periods of extreme wind and wave action.

Compared to a gyre current, a data center vessel 100 operating in a tidal current is designed to have less ballast and more buoyancy. Due to the reversing direction of tidal flows, the vessel 100 is moored at each end to anchors on the ocean floor. The added buoyancy offsets the downward force vector component resulting from the drag of the vessel 100 against the flow. In addition, the mooring drag downward force vector on the vessel 100 is offset by the forward and aft wings 130, pitched to a lift position on each current flow reversal. This alternating pitch adjustment is programmed into an on-board system controller (not shown). Heat produced by the computers and processing equipment (i.e. servers and hard drive arrays) and the onboard electrical system, is extracted through onboard heat exchangers utilizing seawater, along with the flowing seawater over the vessel outer surface.

The reversing nature of a tidal flow means that there are periodic pauses in the power generated by tidal current generators from which the vessel 100 draws its electric power supply. Data centers require reliable, constant power, therefore operating in a tidal current requires the data vessel 100 to have on-board energy storage, its own power generator, or connection to the electrical grid. The tidal current generating system to which the data center vessel 100 is connected may also provide these alternate supplies of power.

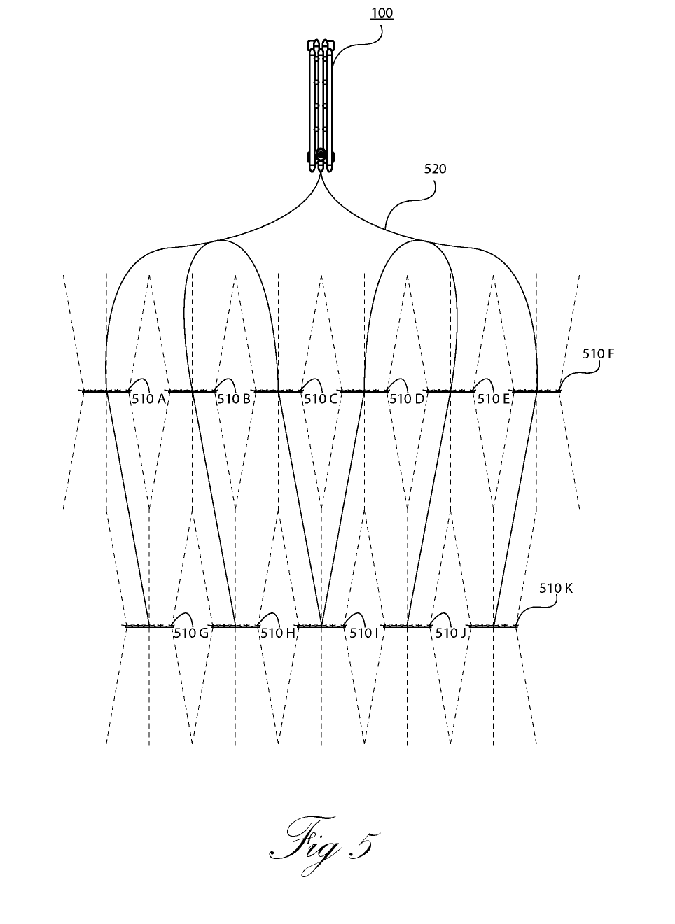

FIG. 5 illustrates a subsurface data center vessel and ocean current turbine system 500 according to an embodiment of the invention. Here, the system 500 is shown looking down on the ocean surface. The data center vessel 100 is coupled via power cables 520 to a number of floating tower frames 510A-K, where K can be any number. The floating tower frames 510A-K each comprises a plurality of ocean turbines that generate electrical power from a marine current. Dash lines represent mooring lines to anchor the floating tower frames 510A-K to the seabed. Further details of the floating tower frames 510A-K can be found in co-pending U.S. patent application Ser. No. 14/217,060, filed on Mar. 17, 2014, and entitled “Floating Tower Frame for Ocean Current Turbine System,” the disclosure of which is incorporated by reference in its entirety.

In another embodiment of the invention, harnessing wave energy generates the electric power supply to the subsurface data center vessel 100. In areas where the form of marine hydrokinetic generator is wave action with minimal current flow, the principal mooring line of the vessel 100 is located on the forward end and the vessel heads into the oncoming wave line. In this situation, elevator wings 130 provide no advantage and may be eliminated since there is minimal current flow. In a wave-powered deployment, the data vessel 100 operates with less ballast providing greater overall buoyancy. The data vessel is held to its operating depth by tension leg moorings (not shown) located forward and aft, and are connected directly below to anchors on the ocean floor to maintain the appropriate operating depth. The tension leg moorings lines are released/retracted by on-board winches (not shown), thereby allowing the vessel 100 to surface or to be submerged to the desired depth, while maintaining a relatively stationary mooring position.

Wave action can be forecast several days in advance and when calm periods prevail, an alternate supply of electrical power is required, either from an on-board source, or from the wave power generator with its own energy storage fueled generating system, or from an onshore power grid to which it is connected.

Heat from the data vessel 100 is extracted in a similar manner to that of the gyre or tidal data vessels where sea water flowing over the hull surface provides cooling along with sea water pumped through on-board heat exchangers, extracting the heat from the data center operating equipment and transporting it back to the open ocean environment.

In another embodiment of the invention, the data center vessel 100 is connected to an onshore data communications network or space satellite system through a wireless communications system or relay systems on unmanned aerial vehicles, balloons, etc., the identification and implementation of all of which are apparent to one of ordinary skill in the art.

In another embodiment of the invention, the vessel 100 may be used for other applications such as, but not limited to reverse osmosis for fresh water production or processing ore from ocean floor mining, etc.

The invention has been described herein using specific embodiments for the purposes of illustration only. It will be readily apparent to one of ordinary skill in the art, however, that the principles of the invention can be embodied in other ways. Therefore, the invention should not be regarded as being limited in scope to the specific embodiments disclosed herein, but instead as being fully commensurate in scope with the following claims.

I claim:

1. A submergible data center vessel comprising:
one or more submergible vessels; and
one or more data centers housed within each of the one or more submergible vessels.

2. The submergible data center vessel of claim 1, wherein the one or more submergible vessels are tubular.

3. The submergible data center vessel of claim 2, wherein the one or more submergible vessels are a plurality of submergible vessels, and one of the plurality of submergible vessels comprises a coning tower.

4. The submergible data center vessel of claim 1, further comprising one or more anchoring lines for anchoring the data center vessel.

5. The submergible data center vessel of claim 1, an electrical conductor for receiving electrical power from an external power source.

6. The submergible data center vessel of claim 5, wherein the external power source is a renewable energy source.

7. The submergible data center vessel of claim 5, wherein the external power source is an onshore power grid.

8. The submergible data center vessel of claim 1, further comprising a data communications line to transfer data between the one or more data centers and the Internet.

9. The submergible data center vessel of claim 1, further comprising a heat exchanger.

10. The submergible data center vessel of claim 9, wherein the heat exchanger dissipates heat away from the one or more data centers into water adjacent to the data center vessel.

11. The submergible data center vessel of claim 1, further comprising one or more elevator wings for adjusting an operating depth of the data center vessel.

12. The submergible data center vessel of claim 3, wherein the one or more submergible vessels are accessible from above an ocean surface by a human.

13. The submergible data center vessel of claim 1, wherein the submergible data center vessel is positively buoyant.

14. The submergible data center vessel of claim 1, further comprising inlet piping coupled to the heat exchanger for drawing cold water.

15. The submergible data center vessel of claim 1, further comprising a snorkel.
